(19) United States
(12) Patent Application Publication
(10) Pub. No.: US 2026/0242211 A1
(43) Pub. Date: Aug. 20, 2026

(54) MANUFACTURING METHOD FOR MICROELECTROMECHANICAL DEVICES AND MICROELECTROMECHANICAL DEVICE THEREOF

(71) Applicant: STMicroelectronics International N.V., Geneva (CH)

(72) Inventors: Giorgio Luigi GRAVINA, Ospitaletto (IT); Marco CARTOTTI, Brembate (IT)

(73) Assignee: STMicroelectronics International N.V., Geneva (CH)

(21) Appl. No.: 19/540,368

(22) Filed: Feb. 13, 2026

(30) Foreign Application Priority Data
Feb. 20, 2025 (IT) 102025000003318

(51) Int. Cl. B81B 7/00; B01L 3/00; B81B 7/02; B81C 1/00

(52) U.S. Cl. CPC B81B 7/0048; B01L 3/502715; B81B 7/007; B81B 7/02; B81C 1/00269; B81C 1/00285; B81C 1/00293; B81C 1/00301; B81C 2203/0118; B81C 2203/0145

(57) ABSTRACT

A manufacturing method for MEMS devices includes: in a first wafer, forming a MEMS structure; forming a cavity and a blind hole in a first face of a second wafer; on the first face, forming a narrowing structure protruding and interposed between the cavity and the blind hole; and sealing the MEMS structure in a chamber delimited by the cavity. Sealing comprises: joining the second wafer to the first wafer to define fluidic paths between the second wafer and the first wafer and to mutually couple the blind hole and the chamber through the fluidic paths, with the narrowing structure forming a section narrowing in the fluidic paths; forming, in a second face opposite to the first face, at least one access opening, communicating with a respective blind hole, to open a respective chimney and to fluidically couple the chamber to an external environment; and closing the chimney.

### BACKGROUND

### TECHNICAL FIELD

The present disclosure relates to a manufacturing method for microelectromechanical (MEMS) devices, and in particular to a sealing method, and to a MEMS device thereof, in particular a gyroscope and/or a multisensor device.

### DESCRIPTION OF THE RELATED ART

As is known, in many applications, several microelectromechanical (MEMS) devices are used, incorporated and sealed in a same package. For example, it is very common to integrate uniaxial or multiaxial gyroscopes and accelerometers in the same chip and therefore in the same package (so-called “multisensor” devices or “combo” sensors).

A frequent issue is linked to the fact that the devices may have optimal operating conditions very different from each other, as in the case of gyroscopes and accelerometers. In fact, in order to reduce consumption due to air friction damping, it is preferable to have the gyroscopes operate in a relatively low-pressure environment, typically comprised between 0.1 mbar and 1 mbar. Gyroscopes are constantly maintained in resonant oscillation and low-pressure conditions favor the maintenance of oscillations, reducing damping and dissipated energy. Accelerometers, on the other hand, normally operate in conditions of higher pressure, for example comprised between 1 mbar and a few atmospheres. Similar issues may also arise with other types of devices operating under different conditions, for example resonators or wake-up systems, in combination with gyroscopes or accelerometers.

A possible solution consists in including different devices in a same cavity or chamber of the package, wherein a pressure level is present corresponding to a compromise between the preferred operating pressures. Solutions of this type are relatively simple to implement, but may be unsatisfactory and affect performance.

According to a different solution, the devices are included in respective sealed and non-communicating chambers. In practice, the devices, for example gyroscopes and accelerometers, are manufactured in a first wafer, while, in a second wafer, caps are provided, and cavities are formed in positions corresponding to respective devices. In the cavities intended for devices operating at a lower pressure, a layer of an absorbent material or getter is also deposited. When the second wafer is joined to the first wafer, for example by glass frit bonding or other wafer bonding technique, or at a successive moment with a dedicated step, the getter is thermally activated in order to absorb the non-noble gases present in the chamber, thus reducing pressure. In this manner chambers sealed with different pressures may be obtained and the respective devices may operate under preferred pressure conditions.

However, even this last solution is not free from limitations. Firstly, especially when particularly high pressures are desired in one of the chambers, the amount of available gaseous nitrogen may saturate the getter and, in this case, the pressure target in the chamber may not be achieved. On the other hand, to include an amount of getter sufficient to prevent saturation, the dimensions (base area and/or height) of the chamber may be greater than what might be sufficient for the sole MEMS devices. Furthermore, solutions using getter materials may be quite sensitive to temperature variations, may generate mechanical and electrical defects in the final device and may not allow reaching the target pressure in the chamber due to incorrect activation and/or due to degassing phenomena. Last but not least, the use of getter materials may be quite expensive and incompatible with process flows that use eutectic mixtures or metal materials as bonding materials: in fact, a getter deposition by argon sputtering and a getter patterning by dedicated photolithographic masks may lead to defects and weaknesses in the bonding layer due to argon degassing phenomena during the bonding step and due to lift-off phenomena of the same masks. A need is therefore felt to improve the robustness of bondings between wafers that use eutectic mixtures or metal materials.

Further solutions that avoid the use of getter materials are mainly based on the formation in the second wafer - following the bonding of the wafers - of one or more chimneys (or vent holes) that allow to create the specific environment for the chambers requiring it. The chimneys need then to be sealed to finalize the package. However, the sealing processes required may present the issue of contamination of the chambers with the sealing materials.

More generally, there are devices or sensors, such as gyroscopes, that require operation in a specific environment with relatively low pressure and controlled atmosphere. Current manufacturing processes that lead to the definition of such specific environments and operating conditions may be quite complex and expensive to implement.

### BRIEF SUMMARY

It is therefore an aim of the present disclosure to overcome or at least partially mitigate the disadvantages and limitations of the state of the art.

According to the present disclosure, a manufacturing method for MEMS devices and a MEMS device thereof are presented as defined in the attached claims.

### BRIEF DESCRIPTION OF THE SEVERAL VIEWS OF THE DRAWINGS

For a better understanding of the present disclosure, preferred embodiments are presented, by way of non-limiting example, with reference to the attached drawings, wherein:

FIG. 1 schematically shows, in a plan view, a MEMS device in accordance with one embodiment of the present disclosure;

FIG. 2 schematically shows a portion of the MEMS device of FIG. 1 in a cross-section thereof taken along the line II-II;

FIGS. 3A-3H schematically show, in the same cross-section as FIG. 2, consecutive processing steps of a manufacturing method for MEMS devices in accordance with one embodiment of the present disclosure; and

FIG. 4 schematically shows the portion of the MEMS device of FIG. 1 in its cross-section taken along the line II-II in accordance with a different embodiment of the present disclosure.

### DETAILED DESCRIPTION

The following description refers to the arrangement shown in the drawings; consequently, expressions such as “above,” “below,” “upper,” “lower,” “top,” “bottom,” “right,” “left” and the like relate to the attached Figures and are not to be construed in a limiting manner.

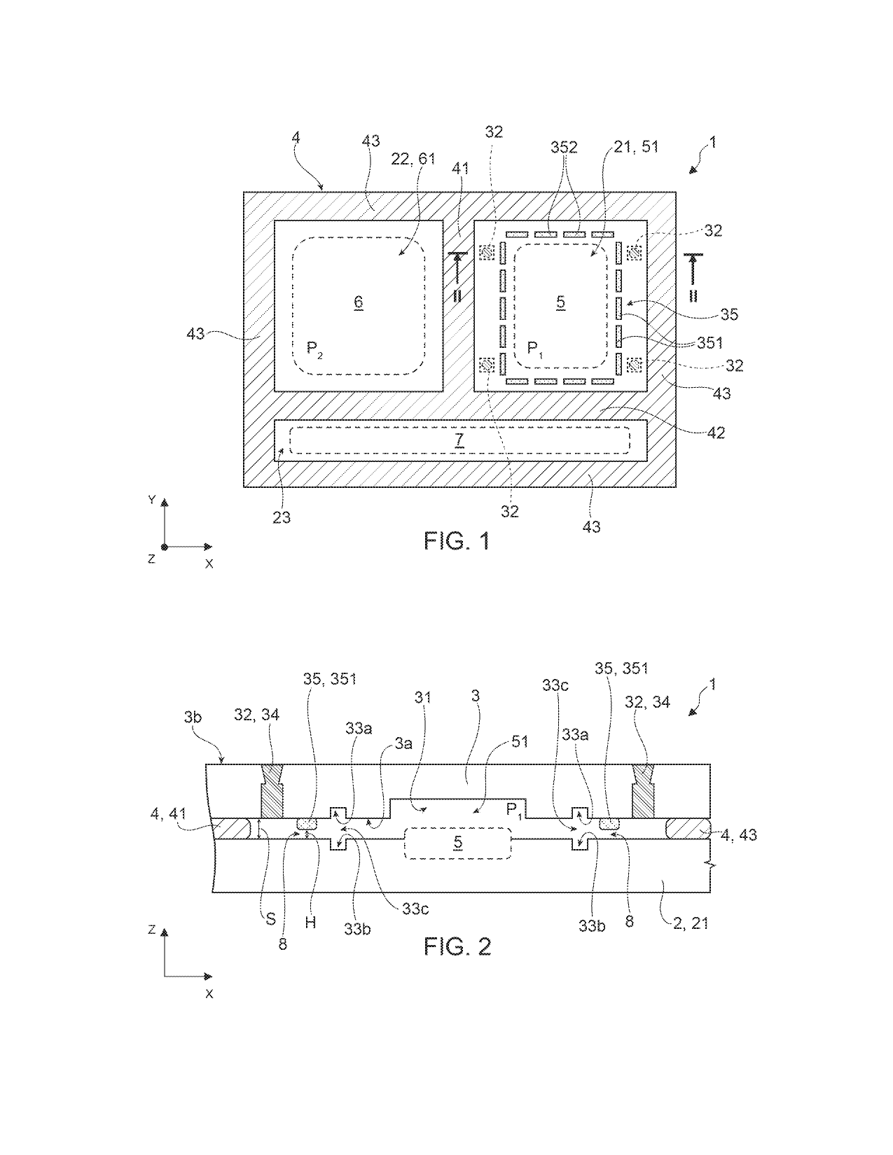

FIGS. 1 and 2 show a microelectromechanical (MEMS) device, hereinafter also simply “device,” according to one embodiment of the present disclosure, indicated as a whole by the number 1 and comprising a support body 2, containing semiconductor material (for example intrinsic and/or doped silicon), and a cap 3, also of semiconductor material. The cap 3 overlies the support body 2 and has an internal surface 3a, arranged facing the support body 2, and an external surface 3b opposite to the internal surface 3a. The cap 3 is also joined to the support body 2 by a bonding layer 4. Considering a reference system of orthogonal axes X, Y, Z, the support body 2 and the cap 3 have a substantially planar shape parallel to the XY-plane and are stacked in the Z-axis direction.

The support body 2 accommodates, in a first region 21 thereof, a first MEMS structure 5, and, in a second region 22 thereof, a second MEMS structure 6. In particular, without this being considered limiting, in the device 1 described below and schematically shown in FIGS. 1 and 2, the first MEMS structure 5 is a structure of a first MEMS sensor operating at a first pressure P₁, for example a gyroscope, while the second MEMS structure 6 is a structure of a second MEMS sensor operating at a second pressure P₂, different from the first pressure P₁, for example an accelerometer. It is however understood that other MEMS sensors that require operating pressures different from each other, such as, but not limited to, resonators, wake-up systems, geophones, bolometers, may be embedded into the device 1. In the attached Figures the first and second MEMS structures 5, 6 are shown only schematically (for illustrative simplicity) but it is understood that they comprise for example movable masses suspended with respect to the support body 2, elastic elements, fixed electrodes, etc., according to the design preferences of the respective MEMS sensor. Furthermore, the support body 2 may comprise a superposition of layers, such as for example semiconductor layers, insulating layers and electrical connections, not shown separately in the attached Figures.

The device 1 also comprises a functional unit 7, accommodated in a third region 23 of the support body 2. Again without limitations, the functional unit 7 comprises components and elements useful for the operation of the MEMS sensors of the device 1, such as for example pads – internally connected to the first and second MEMS structures 5, 6 – for electrical connections towards the outside of the device 1, signal pre-conditioning elements, logic calculation components, further MEMS sensors, etc.

The bonding layer 4 comprises a first separation portion 41, a second separation portion 42 and a frame portion 43. The frame portion 43 surrounds the first, second and third regions 21-23 of the support body 2, the first separation portion 41 divides the first region 21 from the second region 22 (i.e., the first MEMS structure 5 from the second MEMS structure 6) and the second separation portion 42 divides the first and second regions 21, 22 of the support body 2 from the third region 23 of the support body 2. The first and second separation portions 41, 42 and the frame portion 43 are for example in structural continuity. The bonding layer 4 may be formed by a eutectic mixture, for example a germanium-aluminum (AlGe) compound, or by one or more metal materials, for example a gold-gold (Au-Au) compound, or by a compound or paste usable in glass frit bonding processes. Furthermore, a thickness S of the bonding layer 4 determines a distance between the cap 3 and the support body 2. In a non-limiting embodiment, the first and second regions 21, 22 of the support body 2 are arranged side by side along the X-axis and the first separation portion 41 runs centrally to the device 1 with a main extension along the Y-axis.

The first and second MEMS structures 5, 6 are contained in a first chamber 51 and a second chamber 61 of the device 1, respectively. The first and second chambers 51, 61 are defined between the support body 2 and the cap 3. The first and second chambers 51, 61 are also fluidically separated from each other by the first separation portion 41 of the bonding layer 4 and fluidically insulated with respect to the environment external to the device 1. The first chamber 51 is sealed at the first pressure P₁, so that the first MEMS sensor of the device 1 operates at the first pressure P₁, while the second chamber 61 is sealed at the second pressure P₂, so that the second MEMS sensor of the device 1 operates at the second pressure P₂.

With reference in particular to FIG. 2, reference is made hereinafter to the sole first region 21 of the support body 2 and to the corresponding portion of the cap 3, unless otherwise specified. The cap 3 comprises, in detail, a cavity 31 delimiting along the Z-axis (in particular, at the top) the first chamber 51 of the device 1. The cavity 31 is for example a recess of the internal surface 3a of the cap 3 and has a dimension, parallel to the XY-plane, comparable to the area occupied by the first MEMS structure 5 in the first region 21 of the support body 2. In a non-limiting embodiment, the cavity 31 (and the first MEMS structure 5) is arranged centrally in the portion of the cap 3 arranged facing the first region 21 of the support body 2.

The cap 3 exemplarily also comprises one or more trapping holes 33a of the cap 3 (two shown in FIG. 2), that are blind and arranged laterally with respect to the cavity 31. The trapping holes 33a of the cap 3 are for example arranged symmetrically with respect to the cavity 31. The support body 2 exemplarily also comprises one or more trapping holes 33b of the support body 2 (two shown in FIG. 2), that are blind and arranged laterally with respect to the first MEMS structure 5. The trapping holes 33b of the support body 2 are arranged for example aligned with respective trapping holes 33a of the cap 3 and delimit therewith respective traps 33c adjacent to the first chamber 51 of the device 1. The function of the traps 33c is described in more detail below.

With reference also to FIG. 4, the cap 3 further comprises a plurality of plugs 32 (four shown in FIG. 1) that extend in the cap 3 mainly along the Z-axis. In the embodiment of FIG. 2, for example, the plugs 32 extend through the entire cap 3, i.e., from the external surface 3b to the internal surface 3a. In the embodiment of FIG. 4, instead, the plugs 32 extend through the cap 3 from the external surface 3b to an intermediate depth, as will become clearer below; that is, the plugs 32 of FIG. 4 leave corresponding and underlying free portions of the cap 3. The plugs 32 are arranged around the cavity 31 of the cap 3, i.e., around the first chamber 51. In detail, respective projections of the plugs 32 on the support body 2 are at a distance from the first MEMS structure 5. The plugs 32 are, for example, arranged adjacent to portions of the bonding layer 4. In a non-limiting embodiment, the plugs 32 have a circular, and for example tapered, section; furthermore, plugs 32 arranged along a same side of the cavity 31 are aligned with each other and/or pairs of plugs 32 arranged on opposite sides of the cavity 31 are aligned with each other.

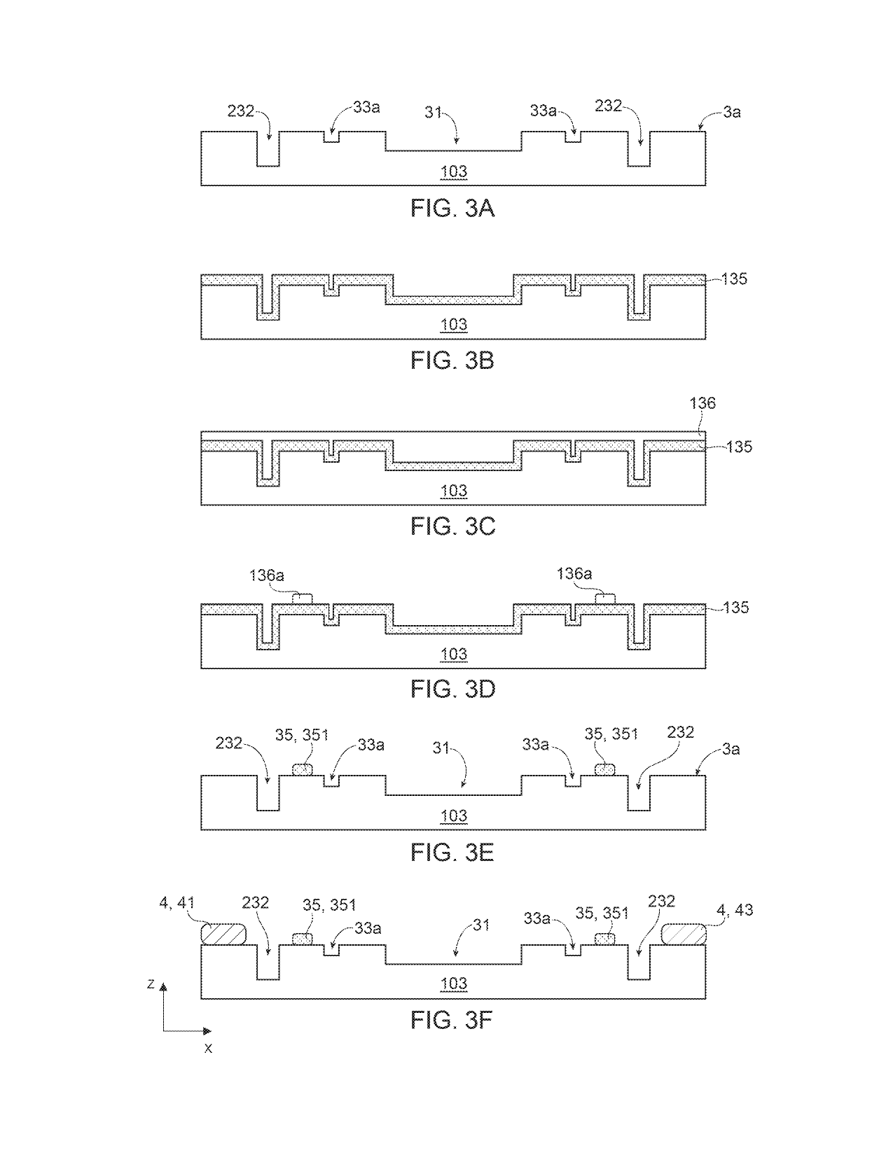

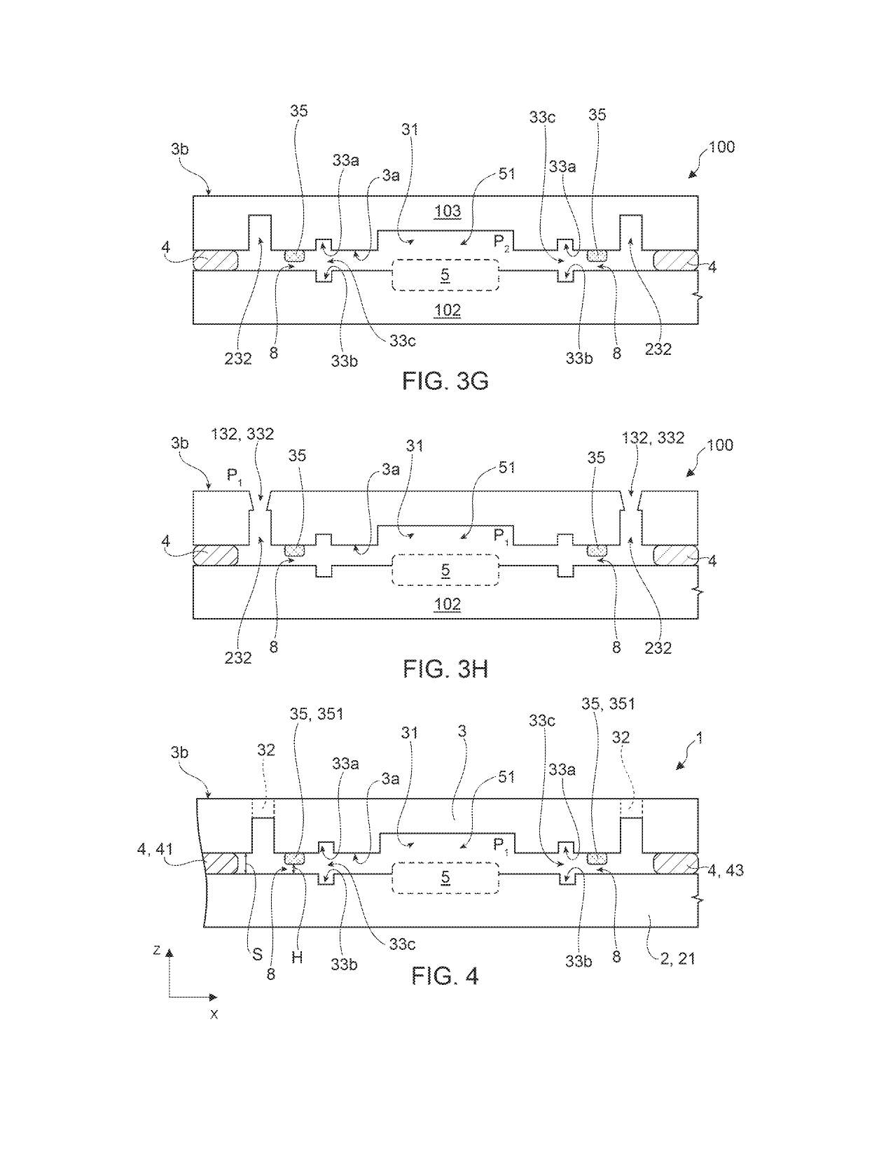

According to one aspect of the present disclosure, the plugs 32 are functional to reaching the first pressure P₁within the first chamber 51, as described in more detail below. In the manufacturing method of the device 1, in fact, chimneys 132 are formed (see FIG. 3H) in positions corresponding to respective plugs 32. The chimneys 132 are then closed with respect to the outside once the first pressure P₁ within the first chamber 51 has been defined, forming the plugs 32 and at the same time hermetically closing the first chamber 51; that is, the plugs 32 occlude the respective chimneys 132. For example, the chimneys 132 are closed by a sealing layer 34 that at least partially fills (along the Z-axis) the chimneys 132, the sealing layer 34 being for example of a different material from the material of the cap 3: in this case, the plugs 32 are therefore formed by the material of the sealing layer 34 (embodiment of FIG. 2; the chimneys 132 are filled, along the Z-axis, completely). Alternatively, the chimneys 132 may be closed by techniques that do not envisage the addition of further material, such as for example laser sealing: in this case, the chimneys 132 are closed by surface migration (or local melting) of the material of the cap 3, such as monocrystalline silicon, resulting in material continuity between the plugs 32 and the rest of the cap 3 (embodiment of FIG. 4; the chimneys 132 are filled, along the Z-axis, only partially). However, in one embodiment such as that shown in FIG. 4, discontinuities – such as for example surface roughness and/or differences in crystallographic orientation – between the plugs 32 and the rest of the cap 3 are still detectable. In general, the cap 3 of the device 1 comprises portions (the plugs), which mainly develop along the Z-axis, at least partially filled – with material that may be different from that of the cap 3 – in positions corresponding to those in which the chimneys 132 are made according to the manufacturing and sealing method of the present disclosure.

The cap 3 finally comprises a narrowing structure 35, extending from the internal surface 3a towards the support body 2. The narrowing structure 35 is interposed between the plugs 32 and the cavity 31 of the cap 3 (i.e., the first chamber 51 of the device 1). In general, the narrowing structure 35 is located on the internal surface 3a of the cap 3 at a respective portion of the support body 2 outside a size of the first MEMS structure 5. In detail, the narrowing structure 35 protrudes from the internal surface 3a of the cap 3 towards the support body 2 to delimit fluidic paths 8 between the plugs 32 and the first chamber 51; that is, the fluidic paths 8 are delimited at the top by the narrowing structure 35 and at the bottom by the support body 2 and fluidically couple portions of the device 1 comprising the plugs 32 with the first chamber 51. In more detail, a thickness of the narrowing structure 35 (along the Z-axis) defines a height H (along the Z-axis) of the fluidic paths 8 that is lower than the thickness S of the bonding layer 4. An H/S ratio is for example lower than 1/2, preferably lower than 1/3, more preferably lower than 1/4 (and typically greater than 1/8); for example, H=1µm and, for a bonding layer 4 formed by glass frit, S=5µm. Where the cap 3 has trapping holes 33a, the narrowing structure 35 is also interposed between the trapping holes 33a and the plugs 32.

Typically, the narrowing structure 35 is physically distinct from the cap 3, i.e., the narrowing structure 35 and the cap 3 are not monolithic. For example, the narrowing structure 35 is formed with a dedicated process step and/or in a different material from that of the cap 3 (the latter being for example of silicon).

As shown in FIG. 1, the narrowing structure 35 surrounds for example the first chamber 51 of the device 1. In detail, the narrowing structure 35 comprises for example first narrowing elements 351 (for example five per side of the first chamber 51 shown in FIG. 1), offset to each other along the Y-axis and having an elongated shape parallel to the Y-axis, and second narrowing elements 352 (for example four per side of the first chamber 51 shown in FIG. 1), offset to each other along the X-axis and having an elongated shape parallel to the X-axis. That is, each first narrowing element 351 is separated from the adjacent first narrowing element 351 and each second narrowing element 352 is separated from the adjacent second narrowing element 352. The narrowing structure 35 is, in other words, a discontinuous frame of the cap 3 to the first chamber 51. In more detail, respective projections of the first and second narrowing elements 351, 352 on the support body 2 are more internal, with respect to the first chamber 51, than respective projections of the plugs 32 on the support body 2. Furthermore, where the narrowing structure 35 is interrupted, the cap 3 exposes its internal surface 3a to the support body 2. In a non-limiting embodiment, the first and second narrowing elements 351, 352 have a rectangular section when viewed in-plan; furthermore, for example, first narrowing elements 351 on corresponding opposite sides of the first chamber 51 are aligned along the X-axis and second narrowing elements 352 on corresponding opposite sides of the first chamber 51 are aligned along the Y-axis.

Each plug 32 of the cap 3 (i.e., according to the method of the present disclosure, each chimney 132) is arranged adjacent to the narrowing structure 35, i.e., in its immediate proximity. For example, as shown in FIG. 1, each plug 32 of the cap 3 is arranged adjacent to, i.e., in proximity to, at least one of the first and/or second narrowing elements 351, 352 of the narrowing structure 35. For example, as shown in the attached Figures, the plugs 32 are arranged adjacent to respective first narrowing elements 351. In alternative embodiments, the plugs 32 are arranged in addition, or alternatively, adjacent to second narrowing elements 352, or are arranged at respective corners of the narrowing structure 35 and therefore adjacent to both first and second narrowing elements 351, 352.

In one embodiment not shown, the narrowing structure has a continuous structure along the entire perimeter of the chamber. In one embodiment not shown, the narrowing structure comprises multiple frames of narrowing elements 351, 352 concentric to each other. In this manner, the possibility of contamination of the chamber is further minimized.

The narrowing structure 35 is formed by one or more dielectric materials, for example an oxide, a nitride, an oxynitride; even more in particular, the narrowing structure 35 is formed by: silicon oxide, silicon carbide, alumina (Al₂O₃), zirconia (ZrO₂), titanium oxide (TiO₂), tantalum oxide (Ta₂O₅), cerium oxide (CeO₂), tantalum nitride (TaN), indium tin oxide (ITO), zinc oxide (ZnO), germanium oxide (GeO₂). Alternatively, the narrowing structure 35 is formed by one or more metal materials, for example: aluminum (Al), aluminum-copper (AlCu), germanium (Ge), gold (Au), titanium-tungsten (TIW), copper (Cu), platinum (Pt), silver (Ag), tungsten (W), titanium (Ti), tantalum (Ta), cobalt (Co), nickel (Ni), palladium (Pd), molybdenum (Mo), chromium (Cr), tin (Sn), indium (In), gallium (Ga), bismuth (Bi), antimony (Sb), rhodium (Rh), ruthenium (Ru). More generally, the material of the narrowing structure 35 is such as not to degas during and after the bonding steps of the cap 3 to the support body 2 (described below) and such as not to introduce complex patterning steps in the current manufacturing process flow of MEMS devices such as the device 1.

According to one aspect of the present disclosure, and as will become clearer below, the narrowing structure 35 reduces (precisely, narrows) the section of the fluidic paths from the chimneys 132 towards the first chamber 51. In detail, the height H of the fluidic paths 8 is such as to significantly reduce the probability that contaminants originating from the sealing steps of the first chamber 51 at the first pressure P₁ (or in any case from the bonding steps of the cap 3 to the support body 2) and accumulating in proximity to the chimneys 132 migrate towards the first chamber 51. For example, the height H of the fluidic paths 8 is of the order of micron units, for example equal to 1 µm. At the same time, the height H of the fluidic paths 8 is such that a fluidic coupling between the outside of the device 1 and the first chamber 51 is ensured prior to the sealing steps of the first chamber 51. Furthermore, the discontinuity along at least one of the axes X and Y of the narrowing structure 35 ensures that such fluidic coupling is maintained even in the event that fluidic paths 8 are partially or completely obstructed at one or more first and/or second narrowing elements 351, 352 during the manufacturing of the device 1. For example, the separation (along the Y-axis) between adjacent first narrowing elements 351 and/or the separation (along the X-axis) between adjacent second narrowing elements 352 is at least equal to the height H of the fluidic paths 8. The traps 33c previously described allow to further reduce the probability of migration of contaminants towards the first chamber 51, by functioning as traps for those particles that can possibly traverse the fluidic paths 8. In an alternative embodiment not shown, however, the traps 33c, i.e., the trapping holes 33a and 33b, may be absent.

The device 1 of FIGS. 1 and 2 is obtained using the manufacturing method, and in particular the sealing method disclosed. FIGS. 3A-3H show a preferred embodiment of the manufacturing method.

A cap wafer 103, for example of monocrystalline silicon and intended to comprise the cap 3 (flipped with respect to what has been shown in FIG. 2, i.e., with the internal surface 3a arranged facing upwards), is patterned by successive photolithographic processes in order to define the cavity 31, the trapping holes 33a (if any) and blind holes 232 (FIG. 3A). In particular, the blind holes 232 are patterned in respective positions corresponding to the future chimneys 132 (and therefore to the future plugs 32). Furthermore, the blind holes 232 are for example patterned to be deeper, with respect to the internal surface 3a, of the cavity 31: in this manner, the opening of the successive chimneys 132 is facilitated (since the amount of residual material to be eliminated to open the chimney is reduced; see FIGS. 3G and 3H) and the probabilities of contaminants migrating towards the future first chamber 51 of the device 1 are further reduced (since part of the chimney opening process is performed in a process step wherein the MEMS structure is absent).

A narrowing layer 135 of the material of the narrowing structure 35 is formed on the internal surface 3a of the previously patterned cap wafer 103, for example by a conformal deposition (FIG. 3B). A protective layer 136 of resist is formed on the narrowing layer 135 (FIG. 3C) for patterning the narrowing structure 35. The protective layer 136 is then photolithographically developed in order to partially expose the narrowing layer 135 (FIG. 3D) and in order to create portions of protective layer 136a corresponding to first and second narrowing elements 351, 352 of the narrowing structure 35 (two portions of protective layer 136a corresponding to two first narrowing elements 351 aligned along the X-axis are shown in the section of FIG. 3D). The exposed narrowing layer 135 is finally etched, for example by dry etching, thus forming the narrowing structure 35 (FIG. 3E).

The cap wafer 103 is then processed in order to form the bonding layer 4 on the internal surface 3a (FIG. 3F). For example, a photolithographic process may be used to form the bonding layer 4 if the bonding layer 4 is to be formed by a eutectic mixture or metal materials; such a photolithographic process comprises, for example, the deposition of a layer of the predefined eutectic mixture, the deposition of a resist and its development, a wet etching to pattern the portions of the bonding layer 4, and their cleaning by argon sputtering. Alternatively, a screen printing process of a glass frit compound or paste may be used if the successive bonding step is to be performed by glass frit wafer bonding technique. In FIG. 3F, the first separation portion 41 and the frame portion 43 are shown for example in section.

The cap wafer 103 is then subject to wafer flipping, assuming the final orientation of the cap 3. Separately, in a sensor wafer 102 of semiconductor material and intended to comprise the support body 2 and the respective components, the first and second MEMS structures 5, 6 (only the first MEMS structure 5 is shown in FIGS. 3G and 3H) and (if any) the trapping holes 33b of the support body 2 are formed. The cap wafer 103 is then joined to the sensor wafer 102 by the bonding layer 4, using for example thermal bonding or bonding of the glass frit technology (FIG. 3G), thus defining the first and second chambers 51, 61 (only the first chamber 51 is shown in FIGS. 3G and 3H), the fluidic paths 8 and the traps 33c. In the following, this joining is referred to as composite wafer 100 and it is understood that it is performed along the Z-axis direction.

The bonding process of the cap wafer 103 to the sensor wafer 102 is performed in an atmosphere at the second pressure P₂ and causes the second chamber 61 to be hermetically closed with respect to the external environment of the composite wafer 100. The second chamber 61 is therefore sealed at the second pressure P₂. The second pressure P₂ is for example comprised between 1mbar and a few atmospheres (atm). The joining of the cap wafer 103 to the sensor wafer 102 in practice also causes the first chamber 51 to be hermetically closed with respect to the external environment: however, the latter undergoes further processes as described below; the second pressure P₂ is therefore a preliminary pressure for the first chamber 51. The first separation portion 41 of the bonding layer 4 ensures a hermetic separation between the first chamber 51 and the second chamber 61, so that the successive processes performed on the first chamber 51 do not affect the pressure condition created in the second chamber 61 (avoiding cross-talk issues between the chambers).

Finally, with reference to FIG. 3H, access openings 332 are formed (for example, by a photolithographic process or by selective etchings) on the external surface 3b in positions corresponding to, and up to, the blind holes 232, creating the chimneys 132 previously described; the access openings 332 are therefore communicating with respective blind holes 232. The chimneys 132 thus formed are through holes of the cap wafer 103 and put in communication (i.e., fluidically couple) the first chamber 51 with the external environment of the composite wafer 100, through the fluidic paths 8. The fluidic paths 8 in fact allow a fluidic exchange between the inside of the first chamber 51, initially at the second pressure P₂ following the bonding process between the cap wafer 103 and the sensor wafer 102, and the external environment. The chimneys 132 may be used, for example, to remove from the first chamber 51 (intended to comprise the first MEMS sensor, which requires for example more stringent and controlled operating conditions, such as a gyroscope) species degassed during the bonding process.

The composite wafer 100 of FIG. 3H is then placed in a controlled atmosphere at the first pressure P₁. Through the chimneys 132 and through the fluidic paths 8, the first chamber 51 reaches the first pressure P₁ predetermined for the operation of the respective first MEMS sensor. The first pressure P₁ is for example comprised between 0.1mbar and 1mbar. It is understood that a single chimney of the plurality of chimneys 132 is sufficient to fluidically couple the first chamber 51 with the outside; however, in order to avoid possible obstructions during the formation step of the chimneys 132, it is preferable to implement redundancy.

Subsequently, the chimneys 132 are closed, always in a controlled atmosphere at the first pressure P₁. For example, as previously mentioned, techniques such as metal sputtering or Spin-On-Glass (SOG) coating may be used that form the sealing layer 34 in order to at least partially fill (along the Z-axis) the chimneys 132 and form the plugs 32. Alternatively, the chimneys 132 may be closed without adding further material, for example by exploiting surface migration phenomena of the material of the cap wafer 103, for example by using laser sealing. Closing the chimneys 132 causes the first chamber 51 to be hermetically closed with respect to the environment external to the composite wafer 100. Finally, the first chamber 51 is therefore sealed at the first pressure P₁. As previously mentioned, according to one aspect of the present disclosure, the presence of the trapping structure 35 allows to block the migration of any residues and particles formed in this closing and sealing step towards the first chamber 51.

The composite wafer 100 then undergoes known final grinding and trimming processes, which lead for example to a thinning of the cap wafer 103, wet cleaning and drying processes (for example by “vacuum prime-vacuum drying”). External contacts and pads useful for driving and extracting signals are then patterned, for example in the third region 23 of the sensor wafer 102; more generally, the operations necessary for defining the final device comprising the first and second MEMS sensors (and having the structure shown in FIGS. 1 and 2) are completed, among which the dicing processes of the composite wafer 100.

The manufacturing method of the present disclosure allows independent adjustment of the operating conditions of the chambers that accommodate the different MEMS sensors embedded in the final device. In particular, the best operating pressure and/or gaseous composition for each MEMS sensor may be selected – in consecutive steps – by the presented method in a flexible and accurate manner. In this manner, the devices manufactured by the present method have performance characteristics with a lower trend to drift over time and are ultimately more reliable.

In addition, by the presence of the narrowing structure, the contamination phenomena of the sensor chambers may be significantly reduced during the bonding and sealing steps. The fluidic paths defined by the narrowing structure allow in fact the fluidic coupling necessary to establish predetermined pressure conditions and, at the same time, block the flow of processing residues towards the active zones of the device (i.e., the chambers). The elements of the narrowing structure ultimately function as barriers for contaminants, for example of the microscopic scale. The defectivenesses caused by the manufacturing processes of the multisensor devices are therefore significantly reduced.

Finally, it is clear that modifications and variations may be made to what has been described and illustrated herein without thereby departing from the scope of the present disclosure, as defined in the attached claims.

For example, the narrowing structure may comprise only the first or second narrowing elements, the chimneys being formed adjacent to ones or the other and the narrowing elements always performing the function of blocking the contaminants accumulating in proximity to the respective chimneys. The number of the first and/or second narrowing elements may be different from what has been shown; at most, for example, the first (or second) narrowing elements may be in a number equal to two per side of the first chamber.

Alternative eutectic mixtures or metal materials for the bonding layer may be, for example: gold-germanium (Au-Ge) compounds; gold-indium (Au-In) compounds; gold-silicon (Au-Si) compounds; gold-tin (Au-Sn) compounds; copper-tin (Cu-Sn) compounds.

Examples according to the present description may comprise:

Example 1. A manufacturing method for microelectromechanical devices comprising:
in a semiconductor first wafer 102, forming a microelectromechanical structure 5; forming a cavity 31 and at least one blind hole 232 in a first face 3a of a semiconductor second wafer 103;
on the first face 3a of the second wafer 103, forming a narrowing structure 35 protruding from the first face 3a of the second wafer 103 and interposed between the cavity 31 and the at least one blind hole 232 of the second wafer 103; and
sealing the microelectromechanical structure 5 in a chamber 51 delimited by the cavity 31 of the second wafer 103,
wherein sealing comprises:
   joining the second wafer 103 to the first wafer 102, with the first face 3a of the second wafer 103 arranged facing the microelectromechanical structure 5, to define fluidic paths 8 between the second wafer 103 and the first wafer 102 and to mutually couple the at least one blind hole 232 and the chamber 51 through the fluidic paths 8, with the narrowing structure 35 forming a section narrowing in the fluidic paths 8;
   forming, in a second face 3b of the second wafer 103 opposite to the first face 3a, at least one access opening 332, communicating with a respective at least one blind hole 232, to open a respective at least one chimney 132 through the second wafer 103 and to fluidically couple the chamber 51 to an external environment; and
   closing the at least one chimney 132, insulating the chamber 51,
   and wherein forming the narrowing structure 35 comprises:
      forming on the first face 3a of the second wafer 103 a narrowing layer 135; and
      patterning the narrowing structure 35 from the narrowing layer 135;

Example 2. The method according to the preceding example, wherein the bonding layer 4 is formed by a eutectic mixture or by one or more metal materials.

Example 3. The method according to example 1, wherein joining the second wafer 103 to the first wafer 102 comprises preliminarily sealing the chamber 51 at a preliminary pressure P₂.

Example 4. The method according to example 1, wherein forming the at least one access opening 332 comprises exposing the chamber 51 to an operating pressure P₁ and wherein closing the at least one chimney 132 seals the chamber 51 at the operating pressure P₁.

Example 5. The method according to example 1, wherein closing the at least one chimney 132 comprises forming a sealing layer 34 in the at least one chimney 132 or closing the at least one chimney 132 without the addition of material.

A manufacturing method for microelectromechanical devices is summarized as including: in a semiconductor first wafer (102), forming a microelectromechanical structure (5); forming a cavity (31) and at least one blind hole (232) in a first face (3a) of a semiconductor second wafer 103; on the first face (3a) of the second wafer (103), forming a narrowing structure (35) protruding from the first face (3a) of the second wafer (103) and interposed between the cavity (31) and the at least one blind hole (232) of the second wafer (103); and sealing the microelectromechanical structure (5) in a chamber (51) delimited by the cavity 31 of the second wafer (103), wherein sealing includes: joining the second wafer (103) to the first wafer (102), with the first face (3a) of the second wafer (103) arranged facing the microelectromechanical structure 5, to define fluidic paths (8) between the second wafer (103) and the first wafer (102) and to mutually couple the at least one blind hole (232) and the chamber (51) through the fluidic paths (8), with the narrowing structure (35) forming a section narrowing in the fluidic paths (8); forming, in a second face (3b) of the second wafer (103) opposite to the first face (3a), at least one access opening (332), communicating with a respective at least one blind hole (232), to open a respective at least one chimney (132) through the second wafer (103) and to fluidically couple the chamber (51) to an external environment; and closing the at least one chimney (132), insulating the chamber (51), and wherein forming the narrowing structure (35) includes: forming on the first face (3a) of the second wafer (103) a narrowing layer (135); and - patterning the narrowing structure (35) from the narrowing layer (135).

The narrowing structure (35) includes narrowing elements (351, 352) including: first narrowing elements (351), offset to each other along a first axis (Y) parallel to the first face (3a) of the second wafer (103), the first narrowing elements (351) also having an elongated shape parallel to the first axis (Y); and second narrowing elements (352), offset to each other along a second axis (X) parallel to the first face (3a) of the second wafer (103) and perpendicular to the first axis (Y), the second narrowing elements (352) also having an elongated shape parallel to the second axis (X).

The narrowing structure (35) is formed adjacent to the at least one blind hole (232).

The narrowing structure (35) surrounds the cavity (31).

The narrowing structure (35) is formed by one or more dielectric materials, for example an oxide, a nitride, an oxynitride, silicon carbide, or by one or more metal materials.

The at least one blind hole (232) is deeper, with respect to the first face (3a) of the second wafer (103), than the cavity (31).

The method includes: forming in the first wafer (102) first trapping holes (33b) which are blind and at a distance from the microelectromechanical structure (5); and forming in the first face (3a) of the second wafer (103) second trapping holes (33a), which are blind, are aligned with respective first trapping holes (33b) and are interposed between the cavity (31) and the narrowing structure (35), wherein joining the second wafer (103) to the first wafer (102) includes defining traps (33c) adjacent to the chamber (51) and delimited by respective first trapping holes (33b) and corresponding second trapping holes (33a).

Joining the second wafer (103) to the first wafer (102) includes forming on the first face (3a) of the second wafer (103) a bonding layer (4), arranged more externally, with respect to the cavity (31), than the at least one blind hole (232), and a ratio (H/S) between a dimension (H) of the fluidic paths (8), along a direction (Z) perpendicular to the first face (3a) of the second wafer (103), and a thickness (S) of the bonding layer (4) is lower than 1/2.

A microelectromechanical device (1) is summarized as including: a support body (2), accommodating a microelectromechanical structure (5); a cap (3), joined to the support body (2) and delimiting a chamber (51) wherein the microelectromechanical structure (5) is sealed; at least one chimney (132), extending through the cap (3), and a respective at least one plug (32), occluding the chimney (132) to insulate the chamber (51) with respect to an environment external to the device (1); and a narrowing structure (35), applied to the cap (3) to protrude towards the support body (2) and interposed between the at least one plug (32) and the chamber (51) to delimit fluidic paths (8) between the at least one plug (32) and the chamber (51).

The narrowing structure (35) includes narrowing elements (351, 352) including: first narrowing elements (351), offset to each other along a first axis (Y) parallel to a face (3a) of the cap (3), the first narrowing elements (351) further having an elongated shape parallel to the first axis (Y); and second narrowing elements (352), offset to each other along a second axis (X) parallel to the face (3a) of the cap (3) and perpendicular to the first axis (Y), the second narrowing elements (352) also having an elongated shape parallel to the second axis (X), wherein the narrowing structure (35) surrounds the chamber (51), and wherein at least one first narrowing element (351) and/or at least one second narrowing element (352) is formed adjacent to the at least one plug (32).

The cap (3) is joined to the support body (2) by a bonding layer (4), arranged more externally, with respect to the chamber (51), of the at least one plug (32), wherein a ratio (H/S) between a dimension (H) of the fluidic paths (8), along a direction (Z) perpendicular to a face (3a) of the cap (3), and a thickness (S) of the bonding layer (4) is lower than 1/2, and the bonding layer (4) is formed by a eutectic mixture or by one or more metal materials.

The device (1) includes traps (33c) adjacent to the chamber (51) and delimited by respective first trapping holes (33b), formed on the support body (2) at a distance from the microelectromechanical structure (5), and corresponding second trapping holes (33a), formed on a face (3a) of the cap (3) in a manner aligned with respective first trapping holes (33b) and interposed between the chamber (51) and the narrowing structure (35).

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A manufacturing method for micro-electromechanical devices comprising:
providing a first semiconductor wafer;
in the first semiconductor wafer, forming a microelectromechanical structure;
providing a second semiconductor wafer;
forming a cavity and at least one blind hole in a first face of the second semiconductor wafer;
on the first face of the second semiconductor wafer, forming a narrowing structure protruding from the first face of the second semiconductor wafer, wherein the narrowing structure is interposed between the cavity and the at least one blind hole,
wherein forming the narrowing structure comprises:
on the first face of the second semiconductor wafer, forming a narrowing layer; and
patterning the narrowing structure from the narrowing layer;
the method further comprising:
sealing the microelectromechanical structure in a chamber delimited by the cavity of the second semiconductor wafer,
wherein sealing comprises:
joining the second semiconductor wafer to the first semiconductor wafer, with the first face of the second semiconductor wafer arranged facing the microelectromechanical structure to define fluidic paths between the second semiconductor wafer and the first semiconductor wafer and to mutually couple the at least one blind hole and the chamber through the fluidic paths, with the narrowing structure partially obstructing the fluidic paths;
in a second face of the second semiconductor wafer opposite to the first face, forming at least one access opening communicating with a respective at least one blind hole to open a respective at least one chimney through the second semiconductor wafer and to fluidically couple the chamber to an external environment; and
closing the at least one chimney to insulate the chamber.

2. The method of claim 1, wherein the narrowing structure comprises narrowing elements.

3. The method of claim 2, wherein the narrowing elements comprise first narrowing elements, offset to each other along a first axis parallel to the first face of the second semiconductor wafer, the first narrowing elements having an elongated shape parallel to the first axis.

4. The method of claim 3, wherein the narrowing elements comprise second narrowing elements, offset to each other along a second axis parallel to the first face of the second semiconductor wafer and perpendicular to the first axis, the second narrowing elements having an elongated shape parallel to the second axis.

5. The method of claim 1, wherein the narrowing structure is formed adjacent to the at least one blind hole.

6. The method of claim 1, wherein the narrowing structure surrounds the cavity.

7. The method of claim 1, wherein the narrowing structure is formed by one or more dielectric materials or by one or more metal materials.

8. The method of claim 7, wherein the one or more dielectric materials selected from a group consisting of: oxide, nitride, or oxynitride.

9. The method of claim 1, wherein the at least one blind hole is deeper, with respect to the first face of the second semiconductor wafer, than the cavity.

10. The method of claim 1, further comprising in the first semiconductor wafer, forming first blind trapping holes at a distance from the microelectromechanical structure.

11. The method of claim 10, further comprising, in the first face of the second semiconductor wafer, forming second blind trapping holes aligned with respective first blind trapping holes, the second blind trapping holes being interposed between the cavity and the narrowing structure.

12. The method of claim 11, wherein joining the second semiconductor wafer to the first semiconductor wafer comprises defining traps adjacent to the chamber and delimited by respective first blind trapping holes and corresponding second blind trapping holes.

13. The method of claim 1, wherein joining the second semiconductor wafer to the first semiconductor wafer comprises forming on the first face of the second semiconductor wafer a bonding layer, the bonding layer being arranged, with respect to the cavity, more externally than the at least one blind hole, and
wherein a ratio between a dimension of the fluidic paths, along a direction perpendicular to the first face of the second semiconductor wafer, and a thickness of the bonding layer is lower than 1/2.

14. A microelectromechanical device comprising:
a support body accommodating a microelectromechanical structure;
a cap, joined to the support body and delimiting a chamber in which the microelectromechanical structure is sealed;
at least one chimney extending through the cap,
at least one plug occluding a respective chimney to insulate the chamber from an environment external to the device; and
a narrowing structure in contact with the cap to protrude towards the support body and interposed between the at least one plug and the chamber to delimit fluidic paths between the at least one plug and the chamber.

15. The device of claim 14, wherein the narrowing structure surrounds the chamber.

16. The device of claim 14, wherein the narrowing structure comprises narrowing elements adjacent to the at least one plug.

17. The device of claim 16, wherein the narrowing elements comprise first narrowing elements offset to each other along a first axis parallel to a first face of the cap, the first narrowing having an elongated shape parallel to the first axis.

18. The device of claim 17, wherein the narrowing elements comprise second narrowing elements offset to each other along a second axis parallel to the face of the cap and perpendicular to the first axis, the second narrowing elements having an elongated shape parallel to the second axis.

19. The device of claim 14, wherein the cap is joined to the support body by a bonding layer arranged, with respect to the chamber, more externally than the at least one plug,
wherein a ratio between a dimension of the fluidic paths, along a direction perpendicular to a face of the cap, and a thickness of the bonding layer is lower than 1/2.

20. The device of claim 14, comprising traps adjacent to the chamber and delimited, on one side, by respective first trapping holes formed on the support body at a distance from the microelectromechanical structure, and, on the other side, by corresponding second trapping holes formed on a face of the cap interposed between the chamber and the narrowing structure, wherein the first and second trapping holes are aligned to each other.
